(19) United States
(12) Patent Application Publication
(10) Pub. No.: US 2009/0136656 A1
(43) Pub. Date: May 28, 2009

(54) Method of manufacturing printed circuit board

(75) Inventors: Dong-Jin Park, Seongnam-si (KR); Seung-Hyun Jung, Suwon-si (KR); Seung-Chul Kim, Cheongju-si (KR); Soon-Jin Cho, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/213,700

(22) Filed: Jun. 23, 2008

(30) Foreign Application Priority Data
Nov. 26, 2007 (KR) 10-2007-0121082

(51) Int. Cl. H05K 3/02

(52) U.S. Cl. 427/96.4

(57) ABSTRACT

A method of manufacturing a printed circuit board is disclosed. The method may include: stacking an anti-plating layer over a copper foil, for a copper clad laminate that includes the copper foil stacked over one side of an insulation layer; forming an intaglio groove, by removing a portion of the anti-plating layer and a portion of the copper clad laminate; stacking a seed layer over a surface of the intaglio groove; forming a plating layer, by plating an inside of the intaglio groove; and removing the anti-plating layer and the copper foil.

### CROSS-REFERENCE TO RELATED APPLICATIONS

This application claims the benefit of Korean Patent Application No. 10-2007-0121082 filed with the Korean Intellectual Property Office on Nov. 26, 2007, the disclosure of which is incorporated herein by reference in its entirety.

### BACKGROUND

1. Technical Field

The present invention relates to a method of manufacturing a printed circuit board having intaglio circuit patterns.

2. Description of the Related Art

With developments in electronic components, fine-line circuit wiring is being employed, in order to provide higher densities in the printed circuit board. This, however, can result in lower adhesion between the metal circuit lines and the insulation, which may cause problems such as the circuit lines being peeled off from the insulation. To improve this, a technique is under development, which includes processing an intaglio groove in the insulation and then filling the groove with metal by a plating process.

The filling of a metal by plating into an intaglio groove having a small width may not pose serious problems even when existing chemicals and processes are employed, but in cases where the width is large, such as the case illustrated in FIG. 1, it can be difficult to obtain a uniform plating thickness using existing techniques, compared to the cases for narrow intaglio grooves. Thus, it may be difficult to obtain a faultless wide circuit pattern 112 without employing a separate leveling process. When an etching process is applied to a plated circuit pattern 112, the inner portion of the intaglio groove can become uncovered, as illustrated in the drawing on the right in FIG. 1.

### SUMMARY

One aspect of the invention provides a method of forming circuit patterns in a simple manner without using a photoresist.

Another aspect of the invention provides a method of manufacturing a printed circuit board. The method includes: stacking an anti-plating layer over a copper foil, for a copper clad laminate that includes the copper foil stacked over one side of an insulation layer; forming an intaglio groove, by removing a portion of the anti-plating layer and a portion of the copper clad laminate; stacking a seed layer over a surface of the intaglio groove; forming a plating layer, by plating an inside of the intaglio groove; and removing the anti-plating layer and the copper foil.

The anti-plating layer can be SOG (spin on glass).

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a printed circuit board according to the related art.

FIG. 2 is a flowchart for a method of manufacturing a printed circuit board according to an embodiment of the invention.

FIG. 3, FIG. 4, FIG. 5, FIG. 6, and FIG. 7 are drawings representing a process flow diagram for a method of manufacturing a printed circuit board according to an embodiment of the invention.

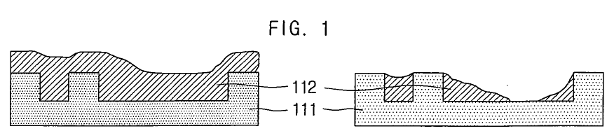

### DETAILED DESCRIPTION

The method of manufacturing a printed circuit board according to certain embodiments of the invention will be described below in more detail with reference to the accompanying drawings. Those components that are the same or are in correspondence are rendered the same reference numeral regardless of the figure number, and redundant explanations are omitted.

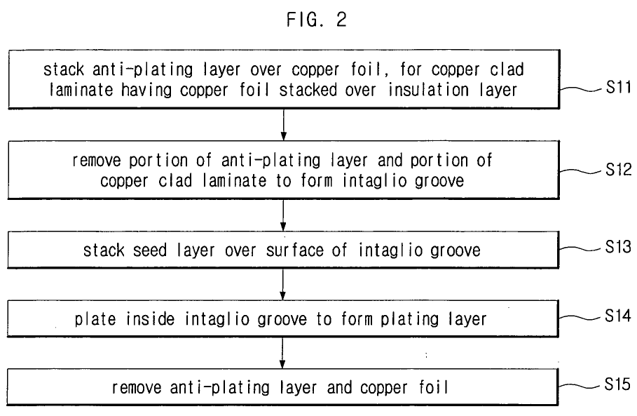

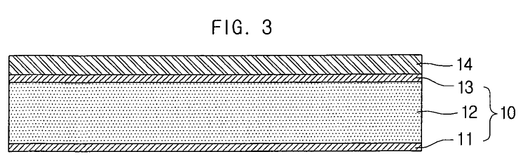

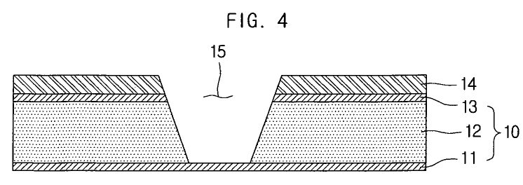

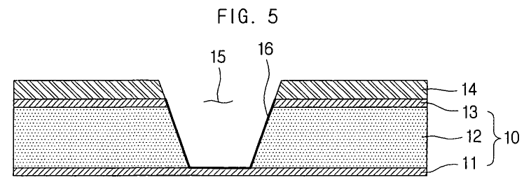

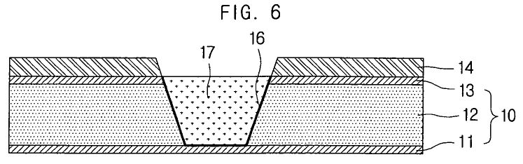

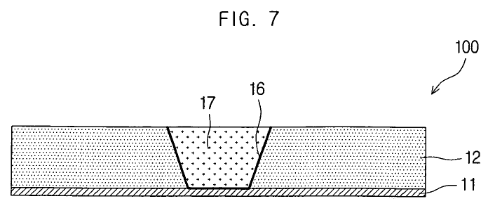

FIG. 2 is a flowchart for a method of manufacturing a printed circuit board according to an embodiment of the invention, while FIG. 3 through FIG. 7 are drawings representing a process flow diagram for a method of manufacturing a printed circuit board according to an embodiment of the invention. In FIGS. 3 to 7, there are illustrated a copper clad laminate 10, copper foils 11, 13, an insulation layer 12, an anti-plating layer 14, an intaglio groove 15, a seed layer 16, and a plating layer 17.

Operation S11 may include, for a copper clad laminate in which a copper foil is stacked over one side of an insulation layer, stacking an anti-plating layer over the copper foil. FIG. 3 illustrates an example of a corresponding process.

The copper clad laminate 10 may have the form of copper foils 11, 13 stacked over both sides of an insulation layer 12, and is an electrical material commonly used in printed circuit boards. It is possible to use a copper clad laminate that has a copper foil stacked only on one side.

The anti-plating layer 14 may be stacked over one side of the copper foil 13. The anti-plating layer 14 can be made from SOG (spin on glass). SOG is widely used as an electrical material, where SOG has a property of not allowing plating on its surface during electroless plating.

Operation S12 may include removing a portion of the anti-plating layer and a portion of the copper clad laminate to form an intaglio groove, where FIG. 4 illustrates an example of a corresponding process.

The intaglio groove 15 may be formed, as illustrated in FIG. 4, using a laser drill. When the inside of the intaglio groove 15 is filled by plating, this will be provided as a circuit pattern. As such, the intaglio groove 15 may be formed in consideration of where the circuit pattern, as well as the pads, etc., is to be placed. Of course, methods known to the public other than laser drilling may also be used.

Operation S13 may include stacking a seed layer over a surface of the intaglio groove, where FIG. 5 illustrates an example of a corresponding process.

The seed layer 16 may be formed by electroless plating. The inside of the intaglio groove 15 may be exposed during the electroless plating and thus may be plated. However, the seed layer 16 may not be stacked over the anti-plating layer 14. The seed layer 16 may be formed by electroless plating performed inside a plating bath.

Operation S14 may include plating inside the intaglio groove to form a plating layer, where FIG. 6 illustrates an example of a corresponding process. By performing an electroplating process, a plating layer 17 may be formed, which will serve as a circuit pattern. Here, the copper foils 11, 13 may be used as lead wires for the plating.

The upper surface of the anti-plating layer 14, on which there is no seed layer 16, may not be plated.

Operation S16 may include removing the anti-plating layer and the copper foil, where FIG. 7 illustrates an example of a corresponding process.

The anti-plating layer 14 and the copper foil 13 may be removed at the same time by grinding. In an alternative method, the anti-plating layer 14 may be physically stripped, after which the copper foil 13 may be removed by etching. To “physically strip” the anti-plating layer means that the anti-plating layer 14 may be removed by applying physical force. As a result, a printed circuit board 100 may be completed as illustrated in FIG. 7. The plating layer 17 may serve as the circuit pattern.

According to certain aspects of the invention as set forth above, an anti-plating layer may be used to selectively plate only the inside of the intaglio groove, which will consequently become the circuit pattern. As such, a printed circuit board can be manufactured without using a photoresist.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board, the method comprising:
stacking an anti-plating layer over a copper foil, the copper foil stacked over one side of an insulation layer to form a part of a copper clad laminate;
forming an intaglio groove by removing a portion of the anti-plating layer and a portion of the copper clad laminate;
stacking a seed layer over a surface of the intaglio groove;
forming a plating layer by plating an inside of the intaglio groove; and
removing the anti-plating layer and the copper foil.

2. The method of claim 1, wherein the anti-plating layer is SOG (spin on glass).
